(19) United States
(12) Patent Application Publication
(10) Pub. No.: US 2003/0019428 A1
(43) Pub. Date: Jan. 30, 2003

(54) Chemical vapor deposition chamber

(75) Inventors: Vincent W. Ku, San Jose, CA (US); Anzhong Chang, San Jose, CA (US); Anh N. Nguyen, Milpitas, CA (US); Ming Xi, Milpitas, CA (US); Xiaoxiong Yuan, Cupertino, CA (US); Juan B. Tuscano JR., Santa Clara, CA (US); Lawrence C. Lei, Milpitas, CA (US); Seshadri Ganguli, Sunnyvale, CA (US); Michael Yang, Palo Alto, CA (US); Chen-An Chen, Milpitas, CA (US); Ling Chen, Sunnyvale, CA (US)

Correspondence Address: APPLIED MATERIALS, INC., 2881 SCOTT BLVD. M/S 2061, SANTA CLARA, CA, 95050, US

(73) Assignee: APPLIED MATERIALS, INC.

(21) Appl. No.: 10/134,206

(22) Filed: Apr. 26, 2002

Related U.S. Application Data
(60) Provisional application No. 60/287,280, filed on Apr. 28, 2001.

(51) Int. Cl. C23C 16/00; C23F 1/00; H01L 21/306

(52) U.S. Cl. 118/715; 156/345.33; 156/345.34; 427/248.1; 427/255.23

(57) ABSTRACT

A processing chamber is adapted to perform a deposition process on a substrate. The chamber includes a pedestal adapted to hold a substrate during deposition and a gas mixing and distribution assembly mounted above the pedestal. The gas mixing and distribution assembly includes a face plate, a dispersion plate mounted above the face plate, and a mixing fixture mounted above the dispersion plate. The face plate is adapted to present an emissivity invariant configuration to the pedestal. The mixing fixture includes a mixing chamber to which a process gas is flowed and an outer chamber surrounding the mixing chamber. The processing chamber further includes an enclosure and a liner installed inside the enclosure and surrounding the pedestal. The liner defines a gap between the liner and the enclosure. The gap has a minimum width adjacent an exhaust port and a maximum width at a point that is diametrically opposite the exhaust port.

This application claims priority from U.S. Provisional Patent Application Serial No. 60/287,280, filed Apr. 28, 2001, which is hereby incorporated by reference herein in its entirety.

### FIELD OF THE INVENTION

The present invention relates to semiconductor device fabrication, and more particularly to chemical vapor deposition apparatus.

### BACKGROUND OF THE INVENTION

The widespread use of semiconductors is due to their usefulness, their cost effectiveness and their unique capabilities. Accompanying the growth in the use, and usefulness, of semiconductors is the development of new processes and materials for the design and manufacture of semiconductor devices together with new or improved manufacturing equipment and hardware. An important recent development is the use of copper (which has about twice the unit conductivity of more commonly used aluminum) for electrical interconnections, or circuit traces within very large scale integrated (VLSI) circuits. The use of copper has permitted faster speeds of operation and greater capability of VLSI circuits but, because copper atoms are highly mobile within certain dielectrics (e.g., silicon dioxide), has led to the need to prevent atoms of copper in the copper circuits from adversely interacting with and creating leakage paths through the various dielectric layers used in the VLSI circuits. One way of preventing such interactions is to provide a “barrier” layer over and/or under the copper, such as a thin layer of tungsten (W).

It is known that a layer of material such as tungsten can be deposited by chemical vapor deposition (CVD) onto exposed surfaces of a semiconductor wafer during VLSI circuit processing. Tungsten, which is a relatively heavy metal having an atomic weight of 183.86, has high temperature resistance and provides suitable protection against the reaction of copper with other materials during the fabrication of VLSI circuits.

It has been known to use tungsten fluoride (WF₆) vapor as a process gas for formation of thin tungsten films by CVD. However, since fluorine tends to attack copper or form an undesired compound, it is preferable to use another tungsten compound as a process gas, such as tungsten hexacarbonyl (W(CO)₆) vapor. Tungsten hexacarbonyl, although a solid at room temperature and atmospheric pressure, may be vaporized under suitable conditions of pressure and temperature to obtain a gaseous phase of the compound which can then be used in CVD processing to form a film or layer of metallic tungsten on a semiconductor wafer.

It is desirable that a layer of metal such as tungsten being deposited by CVD on a semiconductor wafer be uniform in thickness. To achieve this, a chemical vapor compound of the material flowing into a reaction chamber where the semiconductor wafer is being processed should be controlled in flow direction and amplitude so that the vapor is evenly distributed and flows uniformly toward the wafer. This is especially true of materials such as tungsten hexacarbonyl vapor, the molecules of which have relatively high weight and inertia. A CVD process such as deposition of tungsten from tungsten hexacarbonyl vapor is also highly sensitive to temperature variations. It is accordingly desirable to carefully control the temperature environment of the wafer to achieve uniform temperature control across the surface of the wafer to provide for a uniform deposition process.

### SUMMARY OF THE INVENTION

According to an aspect of the invention, there is provided a face plate adapted to be installed above a substrate-support pedestal in a chemical vapor deposition chamber. The face plate includes a substantially planar body having a top surface and a bottom surface and having passages formed through the planar body from the top surface to the bottom surface. The passages are adapted to allow a process gas to flow therethrough. The substantially planar body has an outer periphery, and the face plate includes a flange that extends downwardly from the outer periphery of the substantially planar body to form a recess in which the bottom surface is contained. The flange may be adapted to be thermally coupled to a wall of the deposition chamber.

In at least one embodiment, the passages may form openings in the top surface having a diameter that is less than a diameter of the openings in the bottom surface. Each passage may include an upper cylindrical section adjacent the top surface, a lower cylindrical section adjacent the bottom surface, and a funnel-shaped section which joins the upper cylindrical section to the lower cylindrical section.

The configuration of the inventive face plate, including the recessed bottom surface of the face plate, provides a spacing between the face plate and a substrate undergoing deposition processing such that deposition of reaction by-products on the face plate tends to be prevented. This promotes emissivity invariance of the face plate.

Because of the emissivity invariant profile presented by the face plate to a substrate (held by a pedestal), the substrate may be maintained at a substantially stable and uniform temperature, thereby promoting uniform deposition of a thin film across the surface of the substrate over a large number of processing cycles.

According to another aspect of the invention, there is provided an apparatus for mixing a process gas with a diluent gas. The apparatus includes a body and a mixing chamber formed in the body and adapted to receive a flow of the process gas. The apparatus further includes an outer chamber formed in the body and surrounding the mixing chamber, a first inlet through which the diluent gas flows to the outer chamber, and at least one passage adapted to allow the diluent gas to flow from the outer chamber to the mixing chamber.

In at least one embodiment of the invention, the mixing chamber may be substantially cylindrical and the outer chamber may be annular, with the mixing chamber and the outer chamber being concentric. A gas pressure in the outer chamber may be at a first level and the gas pressure in the mixing chamber may be at a second level that is substantially less than the first level.

The process gas mixing apparatus of the present invention allows for thorough and uniform mixing of the process gas with a carrier or diluent gas, which in turn promotes highly uniform deposition of a thin film on a substrate that is processed in a processing chamber with which the mixing apparatus is associated.

Further features and advantages of the present invention will become more fully apparent from the following detailed description, the appended claims and the accompanying drawings.

### BRIEF DESCRIPTION OF THE DRAWINGS

FIG. 1 is a schematic, vertical sectional view of a CVD chamber provided in accordance with the invention;

FIG. 2 is an enlarged vertical sectional view of a mixing fixture that is part of the CVD chamber of FIG. 1;

FIG. 3 is a schematic horizontal sectional view of the mixing fixture, taken at line III-III of FIG. 2;

FIG. 4 is a bottom perspective view, partially broken away, of a dispersion plate that is part of the CVD chamber of FIG. 1;

FIG. 5 is a schematic, partial bottom plan view of a face plate that is part of the CVD chamber of FIG. 1;

FIG. 6A is an isometric view of the liner of FIG. 1, shown in isolation;

FIG. 6B is a schematic horizontal sectional view of the CVD chamber of FIG. 1, showing a positional relationship between the chamber enclosure and the liner installed within the enclosure; and

FIG. 7 is a vertical sectional view of a portion of the CVD chamber of FIG. 1, showing a feedthrough that allows a process gas to flow from below the chamber to above the chamber.

### DETAILED DESCRIPTION

Overview of CVD Chamber

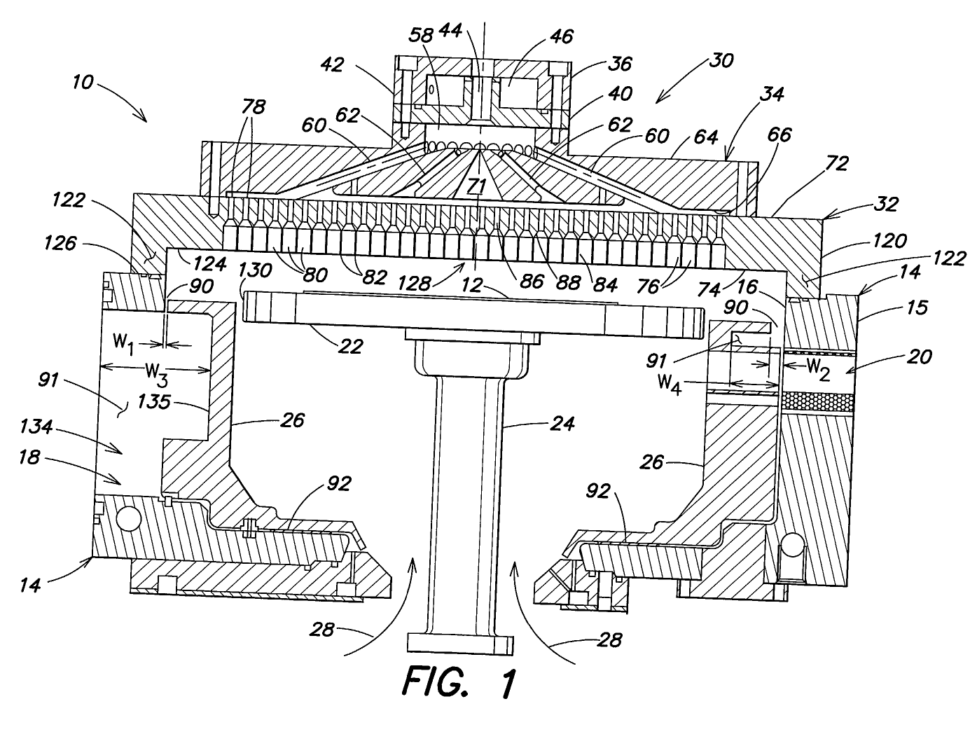

FIG. 1 is a schematic, vertical sectional view of a CVD chamber 10 provided in accordance with the invention. The chamber 10 and its constituent parts are arranged to provide highly uniform and predictable process gas flow in the vicinity of a semiconductor wafer 12 which has been placed in the chamber 10 for chemical vapor deposition processing. The chamber 10 and its constituent parts are also arranged to provide highly uniform and predictable heating of the wafer 12. Because of the uniformity of gas flow and wafer temperature achieved with the design of the chamber 10, high-quality, high-yield chemical vapor deposition can be performed in the chamber 10 even using a difficult-to-manage process gas such as tungsten hexacarbonyl (W(CO)₆) vapor.

The CVD chamber 10 includes a chamber body 14 which forms an enclosure 16. The chamber body 14 includes a circumferential wall 15. The enclosure 16 is hermetically sealable and can be maintained at sub-atmospheric pressure. An exhaust port 18 is formed at one side of the chamber body 14 and is connected to an exhaust pump (not shown) which pumps out the chamber 10. At an opposite side of the chamber body 14 a slit valve 20 is provided. The slit valve 20 is selectively closable and openable to allow access to the interior of the chamber 10 by a wafer handling robot (not shown) which loads the wafer 12 into the chamber 10 for deposition processing, and after processing removes the wafer 12 from the chamber 10. Other pump and/or slit valve positions may be employed.

The wafer 12 is supported on a pedestal 22. Lift pins, which are not shown, may be associated with the pedestal 22 to receive the wafer 12 from the wafer handling robot (not shown) and to lower the wafer 12 to the surface of pedestal 22. The pedestal 22 is mounted on a lift mechanism 24. The lift mechanism 24 operates to raise and lower the pedestal 22 between a load position (not shown) at which the wafer 12 may be placed on the pedestal 22 (e.g., using the slit valve 20), and a process position, as shown in FIG. 1, at which the wafer 12 is held for deposition processing. A heater (not shown) is associated with the pedestal 22 and is arranged to heat the wafer 12 to a suitable temperature for a deposition process.

The chamber body 14, exhaust port 18, slit valve 20, pedestal 22 and lift mechanism 24 may all be provided in accordance with conventional practices. For example, these chamber components may be the same as in a known CVD chamber such as the TxZ chamber available from Applied Materials, Inc., the assignee of this application, and used for TiCl₄ deposition processing.

A liner 26 is installed in the enclosure 16 surrounding the pedestal 22 and adjacent the chamber wall 14. As is known to those who are skilled in the art, the liner 26 is provided to aid in maintenance of the chamber 10, since the liner 26 can be removed for service and cleaning. In addition, according to aspects of the invention that will be described below, the liner 26 is positioned within the chamber 10 to promote an optimal flow of gases within the chamber 10. The liner 26 also serves to minimize temperature variations around the perimeter of the pedestal 22.

In accordance with conventional practice, a flow of purge gas such as argon, nitrogen or some other non-reactive gas is provided as indicated by arrows 28 between the base of the lift mechanism 24 and the liner 26. The purge gas flow 28 through the designed gap between the pedestal 22 and the liner 26 is provided to prevent a back stream of process gas and deposition on the back side of the pedestal 22 (e.g., the side of the pedestal 22 that does not support the wafer 12). Such deposition might change the emissivity of the pedestal 22, and lead to deviations from the design parameters of the deposition process.

Installed above the wafer 12, and the pedestal 22 is a gas mixing and distribution assembly 30. The assembly 30 includes a face plate 32 mounted on the chamber body 14, a dispersion plate 34 mounted on the face plate 32, and a mixing fixture 36 mounted on the dispersion plate 34. Details of these components will be described below.

Mixing Fixture

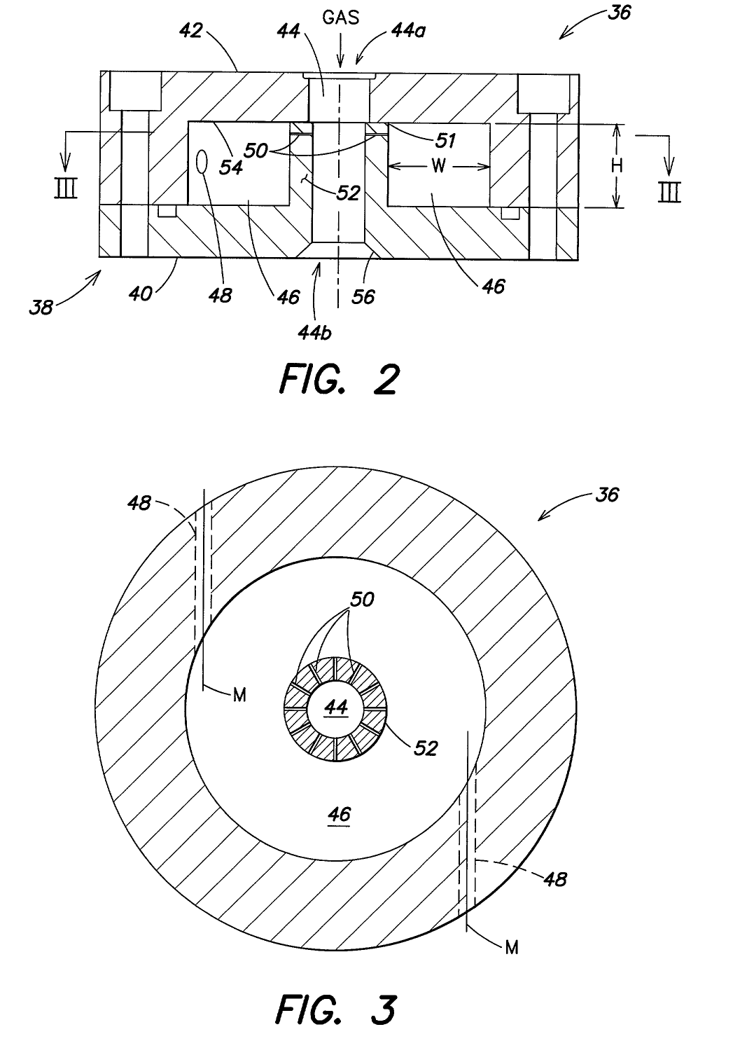

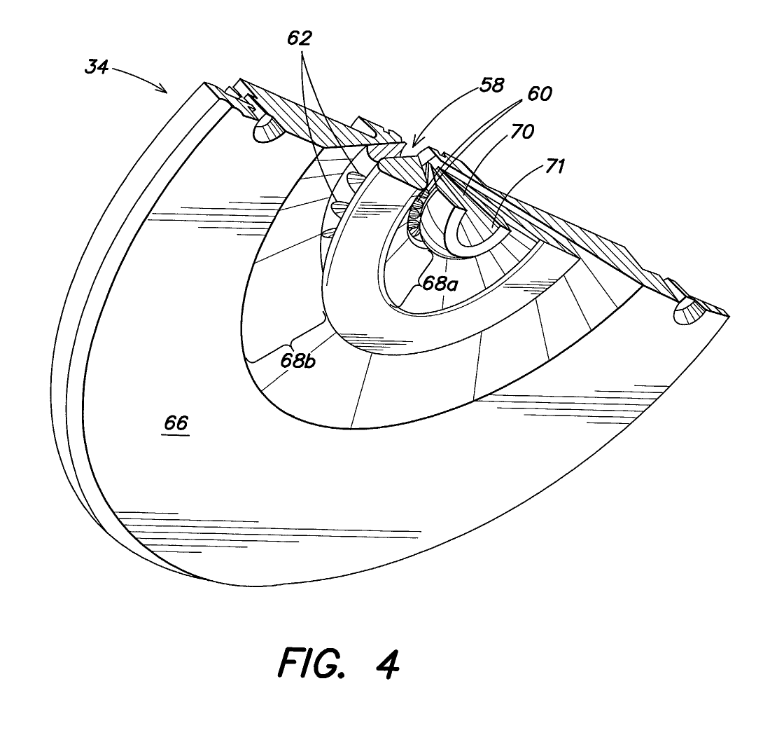

Details of the mixing fixture 36 will now be described with reference to FIGS. 2 and 3. FIG. 2 is an enlarged vertical sectional view of the mixing fixture 36, and FIG. 3 is a schematic horizontal sectional view of the mixing fixture 36.

The mixing fixture 36 includes a body 38 formed of a base 40 and a cap 42. The base 40 is formed of aluminum which provides excellent heat conduction leading to uniformity of temperature in the chambers formed in the body 38. The cap 42 is formed of stainless steel to allow the mixing fixture 36 to be joined by welding to a stainless steel vacuum coupling ring, which is not shown, but which couples the mixing fixture 36 to a conduit (not shown) through which process gas is flowed to the mixing fixture 36. Other materials that have suitable thermal conduction and/or weld properties may be similarly employed for the base 40 and the cap 42. Other techniques for coupling the base 40 and a cap 42 also may be employed.

The body 38 of the mixing fixture 36 defines a substantially cylindrical mixing chamber 44 at a central axis of the mixing fixture 36. The appropriate dimensions of the mixing chamber 44 depend on many factors such as the process being performed, the precursor gas employed, the volume/dimensions of the CVD chamber 10, operating temperature, pressure, flow rate and carrying gas. In one embodiment the mixing chamber 44 has a length, corresponding to the height of the mixing fixture 36, of about two inches. A preferred diameter for the mixing chamber 44 is about 0.45 inch.

Surrounding the mixing chamber 44 is an annular outer chamber 46 which is concentric with mixing chamber 44. As with the mixing chamber 44, the appropriate dimensions of the outer chamber 46 depend on many factors such as the process being performed, the precursor gas employed, the volume/dimensions of the CVD chamber 10, mixing ratio, gas types, pressure, flow rate. In one embodiment, in cross-section, the outer chamber 46 has a height H of about 1 inch and a width W of about 1 inch.

At least one inlet 48 (two inlets are shown in FIG. 3) is in communication with the outer chamber 46 from outside of the body 38 to allow a carrier gas (which also 15 may be considered a diluent gas or a second process gas) to be flowed into the outer chamber 46. As shown in FIG. 3, the inlets 48 are tubes that each have a main axis M. In at least one embodiment, the main axes M do not intersect the central axis of the mixing fixture 36. The diameters of the inlets 48 are not critical and may be, for example, 0.19 inch. Other shapes for the inlets 48 also may be employed.

Narrow passages 50 are formed in a wall 52 of the base 40. The passages 50 allow fluid communication between the outer chamber 46 and the mixing chamber 44. As seen in FIG. 3, the number of passages 50 may be twelve and the passages 50 may be substantially evenly distributed along the circumference of the mixing chamber 44. Other numbers, shapes and/or distributions of passages also may be employed. The passages 50 are dimensioned to provide substantial flow resistance to the carrier gas in the outer chamber 46, but are wide enough to allow adequate flow of carrier gas into the mixing chamber 44. The substantial resistance to gas flow provided by the passages 50 allows a substantially equal rate of flow to be achieved in each of the passages 50. In a preferred embodiment of the invention, the diameter of the passages 50 is 0.02 inch. It is also important that the inlets 48 are oriented so as not to intersect the central axis of the mixing fixture 36 and accordingly are not aligned with any of the passages 50. Consequently, carrier gas does not flow directly from the inlets 48 into any of the passages 50, which aids in allowing substantially equal flow of carrier gas in each of the passages 50. In other words, the inlet or inlets 48 are offset relative to the passages 50 so that the velocity of the carrier gas emerging from the inlets 48 does not affect the local pressure of the carrier gas in the passages 50.

In one embodiment (e.g., for tungsten deposition employing tungsten hexacarbonyl vapor as the process gas), the process gas enters the mixing chamber 44 (via inlet 44a) at a pressure of about 100-200 mTorr. The pressure in the outer chamber 46 is substantially higher, on the order of about 600-700 mTorr. Other pressure ranges may be employed.

Because of the pressure differential between the mixing chamber 44 and the outer chamber 46, the sizing of the passages 50 relative to the outer chamber 46, and the narrow diameter of the passages 50, a substantially equal flow of carrier gas enters the mixing chamber 44 from all directions (i.e. from all of the passages 50). Consequently, there is very even mixing of the carrier gas with the process gas in the mixing chamber 44. The resulting highly uniform dilute process gas mixture promotes highly uniform and predictable deposition of metal film on the wafer 12. Furthermore, the streams of carrier gas entering the mixing chamber 44 via the passages 50 tend to prevent backstreaming of the process gas into the process gas supply line (not shown). As an alternative to the passages 50, a narrow gap (not shown) may be formed between the top of an inner wall 52 of the base 40 and a bottom surface 54 of the cap 42.

In at least one embodiment, a gap may be formed at 51 (FIG. 2) between the top of the wall 52 of the base 40 and the bottom surface 54 of the cap 42 to accommodate different coefficients of thermal expansion of the base 40 and cap 42 (e.g., to prevent grinding contact between the base 40 and cap 42). The gap may be dimensioned such that no significant flow of carrier gas occurs through the gap. In one embodiment the width of the gap is about 0.001 in. at an operating temperature of the mixing fixture 36. Other gap dimensions may be employed.

It is also noted that a chamfer 56 may be provided at a lower edge (i.e. at an outlet 44b) of the mixing chamber 44 to minimize stagnation in gas flow at the outlet of the mixing chamber 44. In a preferred embodiment the chamferred angle is substantially 45°, but this may be varied, for example, in the range of about 30°-60°.

If the mixing fixture 36 is only to be used for mixing a process gas with a carrier gas, then only one inlet 48 need be provided. However, when a second inlet 48 is provided, it is possible to introduce a third gas, such as NH₃, for mixing with the process gas in the mixing chamber 44 (e.g., when it is not desirable to have the carrier gas and the “third” gas delivered via the same inlet 48). Furthermore, the flow paths for the process gas and the carrier gas can be exchanged from the flow paths described above (i.e. the process gas may be flowed to the mixing chamber 44 via outer chamber 46, and the carrier gas may be flowed directly to the mixing chamber 44), if the properties of the gases permit.

Dispersion Plate

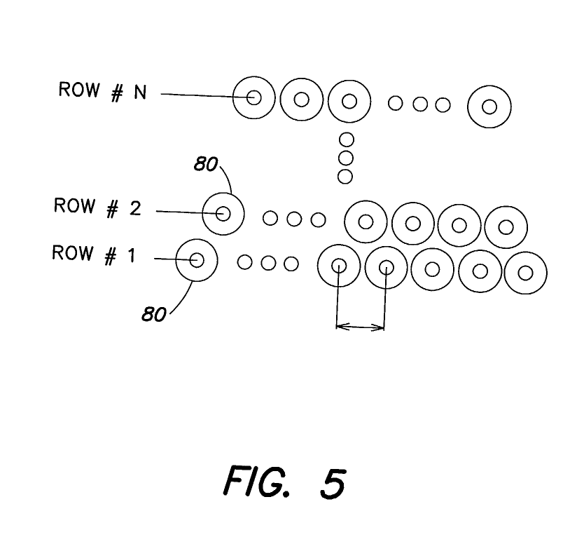

Details of the dispersion plate 34 will now be described with reference to FIGS. 1 and 4. FIG. 4 is a bottom perspective view, partially broken away, of the dispersion plate 34. The dispersion plate 34 is seen in vertical section in FIG. 1.

The dispersion plate 34 is disclosed in a co-pending prior U.S. patent application entitled “Dispersion Plate for Flowing Vaporized Compounds Used in Chemical Vapor Deposition of Films onto Semiconductor Surfaces”, Ser. No. 09/638,506, filed Aug. 15, 2000, commonly assigned with this application and incorporated herein by reference in its entirety. Certain aspects of the dispersion plate 34 will now be described.

The dispersion plate 34 is generally in the form of a disk. As shown in FIG. 4, the dispersion plate 34 includes a cup shaped entrance 58 that may be positioned below the outlet 44b of the mixing chamber 44 of the mixing fixture 36 to receive from the mixing fixture 36 the dilute process gas output from the mixing fixture 36. The dispersion plate 34 is configured to control and direct the flow of a relatively heavy vapor, such as tungsten hexacarbonyl, so that the vapor flows from the dispersion plate 34 in a substantially uniform manner. To this end, the dispersion plate 34 disperses the dilute process gas in horizontal directions by means of passages 60, 62 that extend radially from the center axis of the dispersion plate 34 and are at respective inclined angles. The passages 60, 62 extend from the entrance 58 (which is at a top surface 64 of the dispersion plate 34) to a bottom surface 66 of the dispersion plate 34. Formed in the bottom surface 66 of the dispersion plate 34 are an annular groove 68a which receives the passages 60, and an annular groove 68b which receives the passages 62. A center hole 70 is formed at the bottom center of the entrance 58 and opens downwardly and outwardly into a funnel 71. The funnel 71 and the passages 60 and 62 operate to provide substantially uniform horizontal dispersion of the dilute process gas output by the mixing fixture 36. Suitable dispersion plate 34 materials, passage dimensions and the like are provided in previously incorporated U.S. patent application Ser. No. 09/638,506, filed Aug. 15, 2000.

A temperature sensor (not shown) may be installed in association with the dispersion plate 34 to monitor the temperature of the dispersion plate 34. Signals from the temperature sensor may be provided to a controller (not shown) which controls a heater (not shown) installed in association with the mixing fixture 36. The purpose of this arrangement is to maintain the process gas at a suitable temperature in the gas mixing and distribution assembly 30.

Face Plate

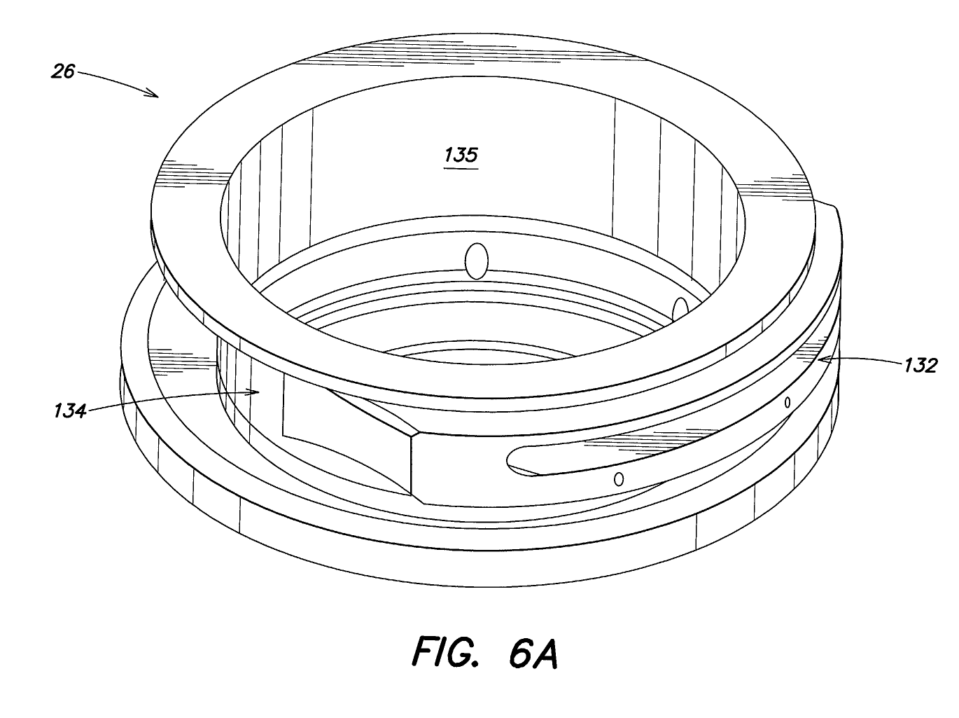

Details of the face plate 32 will now be described with reference to FIGS. 1 and 5. The face plate 32 is a substantially planar body, and may be formed of aluminum for good thermal conductivity throughout the face plate 32. Other thermally conductive materials (that are compatible with the process performed within the chamber 10) also may be employed. Copper may be one such material. The face plate 32 has a top surface 72 that faces the bottom surface 66 of the dispersion plate 34, and a bottom surface 74 that faces the wafer 12 and the pedestal 22. In one embodiment the face plate 32 is about 2 inches thick, although other thicknesses may be used. Numerous passages 76 extend through the face plate 32 from the top surface 72 to the bottom surface 74. In at least one embodiment of the invention, the passages 76 form holes 78 at the top surface 72 and holes 80 at the bottom surface 74. The passages 76 are arranged in a hexagonal or honeycomb fashion (shown in FIG. 5) and extend perpendicularly (vertically) relative to the top surface 72 and the bottom surface 74. Other passage configurations/layouts may be employed.

In one embodiment of the invention, the holes 80 at the bottom surface 74 have a diameter of about 0.270 inches and are at a distance from each other, center-to-center (in the same row (FIG. 5)), of substantially 0.300 inches. Consequently, ridges 82 are formed between the holes 80 having a minimum width between holes of substantially 30/1000 inch. The diameters of the upper surface holes 78 are substantially 0.094 in. Other hole dimensions/spacings may be employed. In general, the appropriate dimensions and spacing of the holes 80 depends on a number of factors such as desired flow conductance, thermal conductance and emissivity. The size of the passages 76, particularly the diameter of the upper surface holes 78, is selected so that face plate 32 does not substantially change the flow of process gas toward the wafer 12, and there is substantially no pressure drop across face plate 32.

Each of the passages 76 has a lower cylindrical portion 84 adjacent the bottom surface 74 of the face plate 32, with the lower cylindrical portions 84 defining therebetween the ridges 82. Each of the passages 76 also has an upper cylindrical portion 86 adjacent the upper surface 72 of the face plate 32. In one embodiment, each upper cylindrical portion 86 has a length of about 0.500 in., and each lower cylindrical portion 84 has a length of about 0.500 in. Other lengths may be employed. Factors which influence selection of these lengths include, for example, face plate thermal conductance and emissivity. Intermediate each upper cylindrical portion 86 and lower cylindrical portion 84, and joining those cylindrical portions to each other, is a funnel-shaped section 88. At the upper half of the face plate 32, in the region perforated by the upper cylindrical portions 86, the face plate 32 has substantial bulk and therefore readily conducts heat so that a uniform temperature is maintained throughout the face plate 32.

In the embodiment of FIG. 1, face plate 32 has an outer periphery 120, from which a flange 122 extends downwardly. The flange 122 defines a recess 124 which contains the bottom surface 74 of the face plate 32. Flange 122 is adapted to be thermally coupled to the circumferential wall 15 of chamber body 14. Heat conduction surfaces are provided at 126 to permit exchange of heat energy between face plate 32 and chamber body 14. In accordance with conventional practices in so-called cold-wall deposition chambers, the temperature of chamber body 14 is kept relatively low. Consequently, face plate 32 is cooled by contact with the chamber body 14 via flange 122.

The passages 76, and more particularly the holes 80 in the bottom surface 74, define a perforated region 128 of bottom surface 74. In at least one embodiment, the perforated region 128 is centered above the pedestal 22 and extends beyond a periphery 130 of pedestal 22. Consequently, the diameter of perforated region 128 is greater than the diameter (in a horizontal plane) of pedestal 22. As a result all of the pedestal 22, including its periphery 130, is faced with perforated region 128 SO that the thermal profile presented to pedestal 22 by face plate 32 is substantially uniform.

The pressure in the chamber 10 during typical deposition processing is on the order of 50-100 mTorr. Consequently, little heat is transferred by conduction from the wafer 12 and the pedestal 22 to the face plate 32 (e.g., during deposition). However, there is substantial radiation of heat from the wafer 12 and the pedestal 22 toward the face plate 32. Because the ridges 82 at the bottom surface 74 of face plate 32 are thin, there is minimal surface area to reflect heat back from the face plate 32 toward the wafer 12. Moreover, the lower cylindrical portions 84 and the funnel-shaped sections 88 of the passages 76 are arranged so as to trap rather than reflect heat radiated toward the face plate 32 by the wafer 12 and the pedestal 22. Further, the substantial bulk of the face plate 32 and the thermally conductive nature of the material from which the face plate 32 is formed serve to transmit thermal energy uniformly along the face plate 32. Still further, the bottom surface 74 of the face plate 32 is substantially flat (e.g., substantially parallel to the pedestal 22 and/or wafer 12) so that any heat reflected from the bottom surface 74 is reflected evenly. Face plate 32 thereby is designed to provide a substantially uniform temperature distribution to the wafer 12, and also to provide “emissivity invariance” such that the temperature environment presented in the processing chamber 10 does not substantially vary over the course of many processing cycles performed in the chamber 10. The emissivity invariance results from keeping the face plate 32 relatively cool by coupling the face plate 32 to the chamber wall 14. Because the face plate 32 is relatively cool, there is little or no deposition of process material on the face plate 32 so that the emissivity of the face plate 32 does not change as processing cycles are performed in the chamber 10.

The uniform temperature distribution provided by the face plate 32 in part results from the bottom surface 74 being flat. In addition, the substantial bulk of the face plate 32 in the region of the reduced diameter upper cylindrical portions 86 and the highly heat conductive material of which the face plate 32 is formed promote free conductance of heat throughout the face plate 32, which also promotes uniformity of temperature. Further, the configuration of the funnel-shaped sections 88 tends to trap heat emitted by the wafer 12, thereby preventing reflection of such heat that could lead to uneven heating of the wafer 12. Moreover, the pedestal 22 is uniformly confronted with the perforated region 128 of face plate 32. Consequently, there is no uneven heating of the wafer 12 by reflection of heat from the face plate 32, so that the wafer 12 can be uniformly and predictably heated by the heating element (not shown) of the pedestal 22. Because the temperature of the wafer 12 can be uniformly controlled, the deposition process occurs with a high degree of uniformity across the wafer 12.

Although the upper portions 86 of the passages 76 are shown as being cylindrical, it is also contemplated to provide a chamfer at each upper surface hole 78 so that each passage 76 exhibits an hour-glass configuration. With such an arrangement the face plate 32 would still have substantial bulk at an intermediate portion thereof to provide for adequate heat conductance throughout face plate 32.

Applicants believe that the spacing of the bottom surface 74 of the face plate 32 relative to the top surface of the wafer 12 is an important factor in avoiding deposition on the bottom surface 74 of process gas by-products that may recoil from the wafer 12. Deposition of such by-products on the bottom surface 74 of the face plate 32 would tend to cause a lack of uniformity in the emissivity of the face plate 32, leading to non-uniform heating of the wafer 12, and interference with the desired uniformity of the deposition process. Factors which influence the selection of this spacing include, for example, the type of process gas employed, the volume/dimensions of the chamber 10, the deposition temperature, pressure, mean free path, and molecular size. Provision of this spacing is facilitated by the recess 124 interposed between the wafer 12 and the bottom surface 74 of the face plate 32. In one embodiment of the invention, the spacing between the bottom surface 74 of the face plate 32 and the top surface of the wafer 12 is at least about 0.680 inches, which is about four times the mean free path of typical process gas vapor molecules at the typical pressure level maintained in the chamber 10 during deposition processing. Other spacings may be employed.

Having described the features of the face plate 32, the dispersion plate 34 and the mixing fixture 36 which together make up the gas mixing and distribution assembly 30, the functions of those components may now be summarized. The mixing fixture 36 provides highly uniform mixing of a process gas with a carrier gas to form a uniform dilute process gas. The dilute process gas is widely and uniformly dispersed in horizontal directions by the dispersion plate 34 to evenly cover the surface of the wafer 12 with impinging dilute process gas. The face plate 32 is interposed between the dispersion plate 34 and the wafer 12 to present a suitably uniform thermal profile to the wafer 12 so that the wafer 12 may be uniformly heated. The uniformity of the impinging process gas and the uniform thermal environment for the wafer 12 tend to promote highly uniform deposition of a thin film across the surface of the wafer 12.

Liner

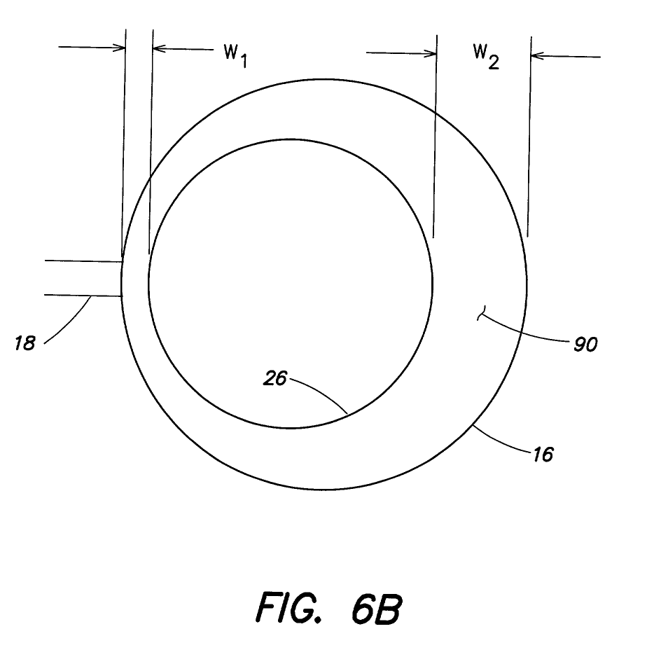

The liner 26 may be essentially conventional in its configuration, but in accordance with the invention is positioned relative to the enclosure 16 of the chamber 10 in a novel manner, and is thermally coupled to the chamber wall 14 of the chamber 10 in a novel manner. These features relating to the liner 26 will be described with reference to FIGS. 1, 6A and 6B.

FIG. 6A is an isometric view of the liner 26, shown in isolation. The liner 26 is generally annular and includes a region 132 that accommodates the slit valve 20 (FIG. 1), and a concave region 134 that defines a portion of a pumping channel 91 (FIG. 1) which is referred to below.

The liner 26 is positioned relative to the enclosure 16 such that a gap 90 is formed therebetween. More particularly, the liner 26 and the enclosure 16 are positioned relative to each other such that the gap 90 is at its narrowest (minimum width shown as W₁ in FIGS. 1 and 6B) adjacent the exhaust port 18, and is at its widest (maximum width shown as W₂ in FIGS. 1 and 6B) at a point that is diametrically opposite from the exhaust port 18. The variable width gap 90 is provided by positioning the liner 26 within the enclosure 16 so that the liner 26 is eccentrically shifted in the direction of the exhaust port 18. This is best seen in FIG. 6B, which is a schematic cross-sectional plan view showing the relative positioning of the enclosure 16, the liner 26, the exhaust port 18, and the gap 90 defined between the enclosure 16 and the liner 26. In FIG. 6B, the gap 90 is substantially exaggerated for the purposes of illustration. The reason for the variation in the width of the gap 90 is to compensate for what would otherwise be an uneven flow of gases in the chamber 10 due to reduced pressure in the vicinity of the exhaust port 18 at one side of the enclosure 16. With the variable width gap 90 provided in accordance with the invention, substantially uniform flows of purge gas and process gas are obtained throughout the chamber 10, which tends to promote uniform deposition on the wafer 12. Rather than (or in addition to) being eccentrically shifted toward the exhaust port 18, the liner 26 may be machined so as to produce the variable gap 90.

In order for the variable width gap 90 to provide uniform flows of purge gas and process gas, a pumping channel 91 (FIG. 1) is formed below the gap 90 and between the liner 26 and the chamber wall 14. That is, the concave region 134 of the liner 26 (FIG. 6A) and the chamber wall 14 (FIG. 1) form a pumping channel 91 when the liner 26 is placed within the chamber 10 as shown in FIG. 1. The pumping channel 91 has a width defined by the distance between an inner wall 135 of the concave region 134 of the liner 26 (FIGS. 1 and 6A) and the chamber wall 14 (FIG. 1). Because of the structure of the exhaust port 18, the pumping channel 91 has a width that is larger adjacent the exhaust port 18. In FIG. 1, the pumping channel width adjacent the exhaust port 18 is indicated by W₃ and the pumping channel width diametrically opposite from the exhaust port 18 is indicated by W₄. In at least one embodiment, the pumping channel 91 has a minimum width (e.g., W₄) that is at least twice the minimum width of the variable width gap 90 (e.g., W₁). In one embodiment, the minimum width of the pumping channel 91 (e.g., W₄) is at least 100 times the minimum width of the variable width gap 90 (e.g., W₁) . Because the liner 26 is shifted inside the chamber 10, the pumping channel 91 has an enhanced width W₄ (e.g., a width that is larger than it would be if the liner 26 was not shifted), which is located at a position where gap 90 has a maximum width W₂, and the pumping channel 91 has a reduced width W₃ (e.g., a width that is smaller than it would be if the liner 26 was not shifted), which is located at a position where gap 90 has a minimum width W₁.

The liner 26 is thermally coupled to the chamber body 14 by means of a thermal bridge 92. The thermal bridge 92 is preferably formed of a heat conductive material that is softer than the material of which the liner 26 is formed, so that the thermal bridge 92 deforms to accommodate any irregularities in the chamber body 14 and/or the liner 26. For example, the liner 26 may be formed of 6061TG aluminum, whereas the thermal bridge 92 may be formed of 6061-0 aluminum, which is one-half as hard as 6061TG aluminum. Because of the softness of the thermal bridge 92, the degree of thermal coupling between the liner 26 and chamber body 14 is predictable notwithstanding any irregularities in the chamber body 14 and/or the liner 26. Moreover, the conductance area of the thermal bridge 92 is configured to provide a proper rate of heat flow between the chamber body 14 and the liner 26. Factors which influence selection of the conductance area of the thermal bridge 92 include, for example, the thermal conductance of the thermal bridge 92, the temperature of the chamber body 14, the process temperature, the chamber pressure, designed surface roughness and material hardness and conductance, temperature differences between each side of the thermal bridge 92, etc. In one embodiment, the thermal bridge 92 has an area of about 22 sq. in. and a thickness of about 0.075 in.

In this manner, the chamber 10 as a whole, including the liner 26, presents a suitable thermal profile to the wafer 12, to assure uniform deposition of a metal layer on the wafer 12. The liner 26 and the pedestal 22 are positioned relative to each other so as to optimize purge efficiency and gas flow.

Feedthrough for Process Gas

A source of process gas (not shown) may be installed above the chamber 10. However, because of the configuration of the chamber 10, it may not be convenient for purposes of operation or maintenance to have the source of process gas above the chamber 10. Accordingly, it may be preferred to have the source of process gas below the chamber 10 and to flow the process gas from below the chamber 10 to the mixing fixture 36 (FIG. 1) via a feedthrough.

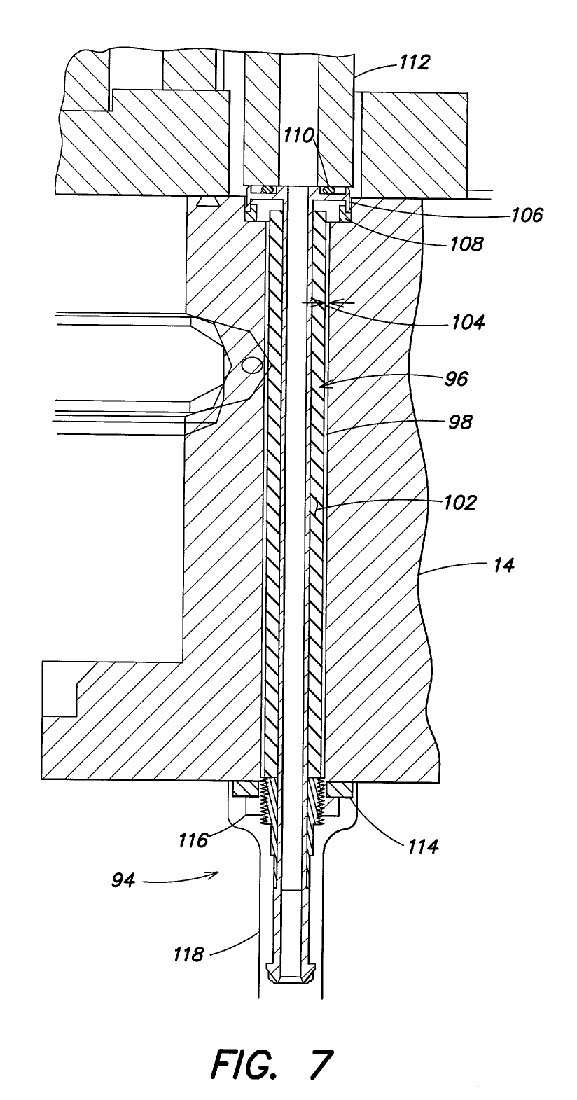

Details of a feedthrough suitable for conveying the process gas from below the chamber 10 to above the chamber 10 are illustrated in FIG. 7, which is a vertical sectional view of a portion of the chamber body 14. In FIG. 7, reference numeral 94 generally indicates the feedthrough. The feedthrough 94 includes a heated tube assembly 96 installed in a bore 98 that has been vertically drilled in the chamber body 14. The heated tube assembly 96 includes a stainless steel (or other suitable material) tube 100 in which the process gas flows and a heater 102 that is cast around the tube 100 in epoxy. The heater 102 may be, for example, a clam-shell heater although other heaters may be used. Also associated with the tube 100 is a thermocouple, which is not separately shown. A gap 104 is defined between the heated tube assembly 96 and the bore 98. The heated tube assembly 96 is mounted at an upper end of the bore 98 by means of a stainless steel (or other suitable material) heat choke 106 and a thermal isolation ring 108. The isolation ring 108 may be formed of a thermally insulative substance such as Vespel (available from Dupont). An O-ring 110 provides a gas tight seal between the heat choke 106 and a heated block 112 (e.g., a metal block with a cartridge heater).

Another thermal isolation ring 114, which may also be formed of Vespel, is provided at a lower end of the bore 98. A nut 116 holds the isolation ring 114 and the heated tube assembly 96 in place. A heater jacket 118 (e.g., a heater filament in silicon rubber) surrounds a lower end of the heated tube assembly 96.

In accordance with conventional practice for a cold-wall deposition chamber, the chamber body 14 may be maintained, for example, at a temperature at about 35° C. On the other hand, in one embodiment of the invention the heater 102 may be operated to maintain a temperature inside the tube 100 in the range of 65°-110° C. Thus, the heated tube assembly 96 can maintain the process gas at a temperature that is high enough to prevent condensation of the process gas, while the gap 104 and other thermal isolation features prevent the heated tube assembly 96 from heating up the chamber body 14.

In operation, a wafer 12 is loaded into the chamber 10 by a wafer handling robot (not shown) via the slit valve 20. The wafer 12 is placed on the pedestal 22 and is raised by the pedestal 22 to the processing position shown in FIG. 1. The chamber 10 is pumped out by an exhaust pump (not shown) to a process pressure of, e.g., 50-100 mTorr. The wafer 12 is heated to a process temperature of, e.g., 400° C. A flow rate of about 2000-5000 c.c. per minute, for example, may be used for the purge gas flows 28.

A process gas such as tungsten hexacarbonyl vapor is flowed to the mixing chamber 44 of the mixing fixture 36. A carrier gas such as argon or another inert gas is flowed to the outer chamber 46 of the mixing fixture 36 via one or more inlets 48. The carrier gas enters the mixing chamber 44 via passages 50 and mixes with the process gas to form a dilute process gas. In at least one embodiment, the pressure of process gas within the mixing chamber 44 may be about 100-200 mTorr and the pressure within the outer chamber 46 may be about 600-700 mTorr. Other pressure ranges may be employed.

The dilute process gas flows from the mixing fixture 36 to the entrance 58 of the dispersion plate 34. By flowing through the passages 60, 62 and the funnel 71 of the dispersion plate 34, the dilute process gas is dispersed in horizontal directions. The dispersed process gas passes through the face plate 32 and impinges on the heated wafer 12. Pyrolysis of the process gas occurs at the wafer 12 and a thin film (e.g., of tungsten) is formed on the surface of the wafer 12. Because of the highly uniform mixing of the process gas with the carrier gas, the uniform flow of the dilute process gas over the wafer 12, and the uniform heating of the wafer 12, all resulting from the process chamber design described herein, the deposition of the thin film on the wafer 12 occurs in a highly uniform manner. Consequently the deposition process can be precisely controlled, and the resulting thin film is of high quality.

Moreover, the design of the liner 26, the (cooled) face plate 32 and the purge gas flow 28 are such that a stable temperature is maintained throughout the deposition process to provide a stable, reliable process.

The foregoing description discloses only exemplary embodiments of the invention; modifications of the above disclosed apparatus which fall within the scope of the invention will be readily apparent to those of ordinary skill in the art. Particularly, although the above-described apparatus has been discussed in connection with using tungsten hexacarbonyl vapor as the process gas, it is contemplated to use the same apparatus with other process gases, such as, for example, gases used for tantalum nitride deposition. Additionally, while the present invention has been described with reference to film deposition on semiconductor wafers, it will be understood that the present invention may be employed to effect film deposition on any substrate (e.g., a glass substrate used for flat panel displays). Further, many of the inventive features of the present invention may be used in other types of chambers such as etch chambers.

Accordingly, while the present invention has been disclosed in connection with a preferred embodiment thereof, it should be understood that other embodiments may fall within the spirit and scope of the invention, as defined by the following claims.

The invention claimed is:

1. A face plate adapted to be installed above a substrate-support pedestal in a chemical vapor deposition chamber, the face plate comprising:
a substantially planar body having a top surface and a bottom surface and having passages formed therethrough from the top surface to the bottom surface, the passages adapted to allow a process gas to flow therethrough, the substantially planar body having an outer periphery; and
a flange that extends downwardly from the outer periphery of the substantially planar body to form a recess in which the bottom surface is contained.

2. The face plate of claim 1, wherein the flange is adapted to be thermally coupled to a wall of the deposition chamber.

3. The face plate of claim 1, wherein the passages form openings in the top surface and form openings in the bottom surface, the openings in the top surface having a diameter that is less than a diameter of the openings in the bottom surface.

4. The face plate of claim 3, wherein each passage includes an upper cylindrical section adjacent the top surface, a lower cylindrical section adjacent the bottom surface, and a funnel-shaped section which joins the upper cylindrical section to the lower cylindrical section.

5. The face plate of claim 4 wherein:
the upper cylindrical sections are adapted to provide the face plate with a larger thermal conductance near the upper cylindrical sections than near the lower cylindrical sections; and
the lower cylindrical sections and funnel-shaped sections are adapted to trap and not reflect heat radiated toward the bottom of the face plate by a substrate positioned on the pedestal of the chamber.

6. A face plate adapted to be installed above a substrate-support pedestal in a chemical vapor deposition chamber, the face plate comprising:
a substantially planar body having:
a top surface;
a bottom surface; and
passages formed from the top surface to the bottom surface, the passages adapted to allow a process gas to flow therethrough, the passages forming openings in the bottom surface and forming openings in the top surface, the openings in the top surface having a diameter that is less than a diameter of the openings in the bottom surface;
wherein the openings in the top surface are adapted to provide the face plate with a larger thermal conductance near the openings in the top surface than near the openings in the bottom surface; and
wherein the openings in the bottom surface are adapted to trap and not reflect heat radiated toward the bottom of the face plate by a substrate positioned on the pedestal of the chamber.

7. The face plate of claim 6, wherein each passage includes an upper cylindrical section adjacent the top surface, a lower cylindrical section adjacent the bottom surface, and a funnel-shaped section which joins the upper cylindrical section to the lower cylindrical section.

8. A face plate adapted to be installed above a substrate-support pedestal in a chemical vapor deposition chamber, the pedestal having a first diameter in a plane, the face plate comprising:
a substantially planar body having a top surface and a bottom surface and having passages formed therethrough from the top surface to the bottom surface to define a perforated region of the bottom surface, the passages adapted to allow a process gas to flow therethrough, the perforated region of the bottom surface having a second diameter in the plane that is larger than the first diameter of the pedestal.

9. The face plate of claim 8, wherein the substantially planar body has an outer periphery and further comprising a flange that extends downwardly from the outer periphery of the substantially planar body.

10. The face plate of claim 8, wherein the passages form openings in the top surface and form openings in the bottom surface, the openings in the top surface having a diameter that is less than a diameter of the openings in the bottom surface.

11. The face plate of claim 10, wherein each passage includes an upper cylindrical section adjacent the top surface, a lower cylindrical section adjacent the bottom surface, and a funnel-shaped section which joins the upper cylindrical section to the lower cylindrical section.

12. A method for use within a chemical vapor deposition chamber having a substrate-support pedestal, the method comprising:
providing a face plate having:
a top surface;
a bottom surface; and
passages formed from the top surface to the bottom surface, the passages adapted to allow a process gas to flow therethrough, the passages forming openings in the bottom surface and forming openings in the top surface, the openings in the top surface having a diameter that is less than a diameter of the openings in the bottom surface;
wherein the openings in the top surface are adapted to provide the face plate with a larger thermal conductance near the openings in the top surface than near the openings in the bottom surface; and
wherein the openings in the bottom surface are adapted to trap and not reflect heat radiated toward the bottom of the face plate by a substrate positioned on the pedestal of the chamber;
positioning the face plate near the pedestal;
positioning a substrate on the pedestal;
flowing a process gas through the face plate; and
depositing a film on the substrate with the process gas.

13. A processing chamber adapted to perform a deposition process on a substrate, comprising:
an enclosure;
a pedestal positioned in the enclosure and adapted to hold a substrate during deposition;
a face plate positioned to deliver a process gas to a substrate positioned on the pedestal, the face plate comprising:
a top surface;
a bottom surface; and
passages formed from the top surface to the bottom surface, the passages adapted to allow a process gas to flow therethrough, the passages forming openings in the bottom surface and forming openings in the top surface, the openings in the top surface having a diameter that is less than a diameter of the openings in the bottom surface;
wherein the openings in the top surface are adapted to provide the face plate with a larger thermal conductance near the openings in the top surface than near the openings in the bottom surface; and
wherein the openings in the bottom surface are adapted to trap and not reflect heat radiated toward the bottom of the face plate by the substrate positioned on the pedestal of the chamber;
a dispersion plate positioned to deliver the process gas to the face plate and having a center axis, a top surface and a bottom surface and a plurality of passages extending radially from the center axis at respective inclined angles from the top surface to the bottom surface; and
a mixing fixture positioned to deliver the process gas to a central portion of the dispersion plate and having:
a body;
a mixing chamber formed in the body and adapted to receive a flow of the process gas;
an outer chamber formed in the body and surrounding the mixing chamber;
a first inlet through which a diluent gas flows to the outer chamber; and
at least one passage adapted to allow the diluent gas to flow from the outer chamber to the mixing chamber so as to dilute the process gas.

14. An apparatus adapted to mix a process gas with a diluent gas, comprising:
a body;
a mixing chamber formed in the body and adapted to receive a flow of the process gas;
an outer chamber formed in the body and surrounding the mixing chamber;
a first inlet through which the diluent gas flows to the outer chamber; and
at least one passage adapted to allow the diluent gas to flow from the outer chamber to the mixing chamber.

15. The apparatus of claim 14, wherein the body has a central axis and the mixing chamber is formed in the body at the central axis.

16. The apparatus of claim 14, wherein the mixing chamber is substantially cylindrical and the outer chamber is annular, and the mixing chamber and the outer chamber are concentric.

17. The apparatus of claim 16, wherein the at least one passage includes a plurality of passages connecting the outer chamber to the mixing chamber.

18. The apparatus of claim 17, wherein the passages are substantially evenly distributed along the circumference of the mixing chamber.

19. The apparatus of claim 18, wherein the passages are twelve in number.

20. The apparatus of claim 18, wherein each of the passages has a diameter of substantially 0.02 inch.

21. The apparatus of claim 14, wherein a gas pressure in the outer chamber is at a first level and a gas pressure in the mixing chamber is at a second level that is substantially less than the first level.

22. The apparatus of claim 21, wherein the first level is in the range of 600-700 mTorr and the second level is in the range of 100-200 mTorr.

23. The apparatus of claim 14, wherein the first inlet is a tube that has a main axis which does not intersect a central axis of the body.

24. The apparatus of claim 14, wherein the mixing chamber is substantially cylindrical and has a chamferred lower edge.

25. The apparatus of claim 14, further comprising a second inlet positioned to conduct the diluent gas or a third gas to the outer chamber.

26. The apparatus of claim 25, wherein the first and second inlets are tubes that have respective main axes which do not intersect a central axis of the body.

27. An Apparatus adapted to mix a process gas with a diluent gas, comprising:
a body having a central axis;
a mixing chamber formed in the body at the central axis and adapted to receive a flow of the process gas;
an outer chamber formed in the body and surrounding the mixing chamber, the outer chamber being in fluid communication with the mixing chamber; and
an inlet through which the diluent gas flows to the outer chamber.

28. The apparatus of claim 27, wherein the outer chamber is in fluid communication with the mixing chamber by means of a plurality of passages radiating outwardly from the mixing chamber to the outer chamber.

29. The apparatus of claim 28 wherein the passages are sized so as to provide substantial resistance to flow of the diluent gas from the outer chamber to the mixing chamber.

30. An apparatus adapted to mix a process gas with a diluent gas, comprising:
a first chamber adapted to receive the process gas at a first pressure;
a second chamber adjacent the first chamber and adapted to receive the diluent gas and to hold the diluent gas at a second pressure that is higher than the first pressure; and
at least one passage adapted to allow the diluent gas to flow from the second chamber to the first chamber, the at least one passage providing substantial resistance to flow of the diluent gas from the second chamber to the first chamber.

31. The apparatus of claim 30, wherein a difference between the first pressure and the second pressure is in the range of 400-600 mTorr.

32. The apparatus of claim 30, wherein the second chamber surrounds the first chamber and the at least one passage includes a plurality of passages radiating outwardly from the first chamber.

33. A method of mixing a process gas and a diluent gas, comprising:
flowing the process gas to a mixing chamber of a mixing fixture;
flowing the diluent gas to an outer chamber that surrounds the mixing chamber; and
allowing the diluent gas to enter the mixing chamber from the outer chamber.
